(19) United States
(12) Patent Application Publication
(10) Pub. No.: US 2012/0159280 A1
(43) Pub. Date: Jun. 21, 2012

(54) METHOD FOR CONTROLLING NONVOLATILE MEMORY APPARATUS

(75) Inventors: Wun Mo YANG, Ichon-si (KR); Kyeong Rho KIM, Ichon-si (KR); Myung Suk LEE, Ichon-si (KR); Jeong Soon KWAK, Ichon-si (KR)

(73) Assignee: Hynix Semiconductor Inc., Ichon-si (KR)

(21) Appl. No.: 13/194,231

(22) Filed: Jul. 29, 2011

(30) Foreign Application Priority Data
Dec. 21, 2010 (KR) 10-2010-0131950

(51) Int. Cl. H03M 13/00

(52) U.S. Cl. 714/754; 714/E11.03

(57) ABSTRACT

There is provided a method for controlling a nonvolatile memory apparatus in a nonvolatile memory system including a host interface, a memory controller, and a memory area. The method includes: checking a number of ECC fail bits, determining whether or not to replace a corresponding block, and replacing the block, while a read command provided from the host interface is performed; and replacing a block, which was not replaced during the read operation, with a block to be used as a replacement target during a write operation.

### CROSS-REFERENCES TO RELATED APPLICATION

The present application claims priority under 35 U.S.C. §119(a) to Korean Application No. 10-2010-0131950, filed on Dec. 21, 2010, in the Korean Intellectual Property Office, which is incorporated herein by reference in its entirety as if set forth in full.

### BACKGROUND

1. Technical Field

Various embodiments of the present invention relate to a nonvolatile memory apparatuses and methods for controlling thereof. In particular, certain embodiments relate to a method for controlling a nonvolatile memory apparatus to manage a block.

2. Related Art

A flash memory is widely used in a mobile communication terminal, a portable media player, a digital camera, a mobile storage medium and so on. In order to use a flash memory as a storage medium, the data integrity should be guaranteed. However, bit errors may occur in a flash memory due to its physical property. Therefore, the flash memory should be able to detect and correct the bit error. A typical flash memory uses an error correction code (ECC) circuit to detect and correct a bit error.

The number of bit errors which may be corrected by using the ECC circuit is limited.

When a fail occurs during a read operation while a maximum number of ECC correction bits is exceeded through frequent read and write operations, the read operation which is currently performed is processed as a fail. When the number of ECC correction bits increases, it may indicate that a read fail is highly likely to occur. For this reason, the data stored in the flash memory may not be trusted.

### SUMMARY

Accordingly, there is a need for an improved method for controlling a nonvolatile memory apparatus which manages memory blocks therein.

To attain the advantages and in accordance with the purposes of the invention, as embodied and broadly described herein, one exemplary aspect of the present invention may provide a method for controlling a nonvolatile memory apparatus in a nonvolatile memory system including a host interface, a memory controller, and a memory area. The method may include: checking a number of ECC fail bits, determining whether or not to replace a corresponding block, and replacing the block, while a read command provided from the host interface is performed; and replacing a block, which was not replaced during the read operation, with a block to be used as a replacement target during a write operation.

In another exemplary aspect of the present invention, there is provided a method for controlling a nonvolatile memory apparatus in a nonvolatile memory system including a host interface, a memory controller, and a memory area. The method includes: checking a number of ECC fail bits, discriminating whether a corresponding block is a dirty block caused by read disturbance or a worn-out dirty block, and setting a replace flag for whether or not to replace the corresponding block, while a read command provided from the host interface is performed; and replacing a block, in which the replace flag is set, with a block to be used as a replacement target during a write operation.

In another exemplary aspect of the present invention, there is provided a method for controlling a nonvolatile memory apparatus in a nonvolatile memory system including a host interface, a memory controller, and a memory area. The method includes: checking a number of ECC fail bits to determine whether a corresponding block is a dirty block or not, setting the dirty block to a block to be replaced, and discriminating whether or not to reuse the dirty block, while a read command provided from the host interface is performed; and replacing the dirty block, which was not replaced while the read command was performed, with a block to be used as a replacement target during a write operation.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a block diagram of a nonvolatile memory apparatus according to one embodiment.

FIG. 2 is a flow chart showing a method for controlling a read operation based on FIG. 1.

FIG. 3 a flow chart showing a method for controlling a write operation based on FIG. 1.

### DETAILED DESCRIPTION

Hereinafter, a method for controlling a nonvolatile memory apparatus according to the present invention will be described below with reference to the accompanying drawings through exemplary embodiments.

The block diagram may represent a part of a module, a segment, or a code including one or more instructions for executing specific logic functions. Furthermore, in some substitute embodiments, functions described in blocks may be executed out of sequence. For example, two blocks illustrated continuously may be executed at the same time or may be executed in reverse order according to the corresponding functions.

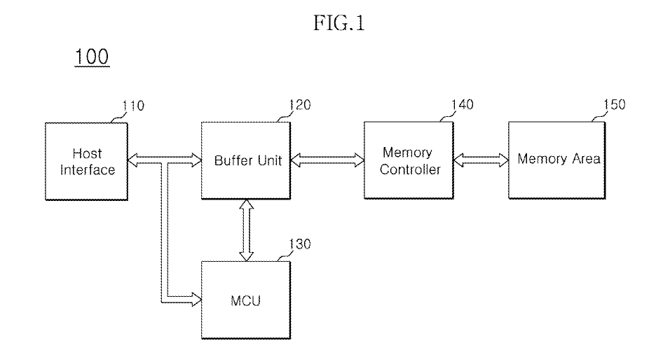

FIG. 1 is a block diagram of a nonvolatile memory apparatus according to one exemplary embodiment. In this embodiment, the nonvolatile memory apparatus may be a memory apparatus using a NAND flash memory.

As shown in FIG. 1, the nonvolatile memory apparatus 100 may include a host interface 110, a buffer unit 120, a micro control unit (MCU) 130, a memory controller 140, and a memory area 150.

The host interface 110 is coupled to the buffer unit 120. The host interface 110 is configured to transmit and receive a control command, an address signal, and a data signal between an external host (not illustrated) and the buffer unit 120. The interface method between the host interface 110 and the external host may include any one of SATA (Serial Advanced Technology Attachment), PATA (Parallel Advanced Technology Attachment), SCSI, Express Card, and PCI-Express, and is not limited thereto.

The buffer unit 120 is configured to buffer output signals from the host interface 110 or temporarily store mapping information between a logic address and a physical address, block allocation information of the memory area, the erase number of blocks, and data received from outside. The buffer unit 120 may include a buffer using SRAM (Static Random Access Memory) or DRAM (Dynamic Random Access Memory).

The MCU 130 is configured to transmit and receive a control command, an address signal, and a data signal to and from the host interface 110 or control the memory controller 140 based on such signals.

Meanwhile, the memory controller 140 is configured to receive input data and a write command from the host interface 110 and control the input data to be written in the memory area 150. Similarly, when the memory controller 140 receives a read command from the host interface 110, the memory controller 140 reads data from the memory area 150 and controls the read data to be outputted to the outside.

In particular, the memory controller 140 according to the embodiment sets a threshold value on a number of ECC correction bits, and controls an operation of replacing a block on the basis of the threshold value. Therefore, as blocks are efficiently managed before the number of ECC correction bits is exceeded, it is possible to increase the reliability of data and the reliability of the memory apparatus.

More specifically, when the number of ECC correction bits approaches the threshold value set by the memory controller 140, the memory controller 140 determines whether or not to perform correction during read latency, and sets a flag. That is, when a block can be replaced within the corresponding latency, effective pages are copied in a free block, and when the block cannot be replaced within the corresponding latency, a replace flag is set to indicate that a subsequent replacement operation is to be performed during a write operation. After that, whether to replace the corresponding block or to perform only the write operation is set according to whether the replace flag is set or not, during the write operation.

That is, a block in which the number of ECC correction bits approaches the threshold value is considered as a dirty block. In such a dirty block, a read fail is highly likely to occur during a subsequent write operation. Therefore, when the corresponding block is copied into another block before the number of ECC correction bits is exceeded or it is determined that the time is not sufficient, a replace flag is set to indicate that the replacement of the corresponding block or the copying operation is needed during an operation requiring a long time, such as a subsequent write operation.

During a subsequent write operation, when the replace flag is set in a target in which data is to be written, whether or not such an operation can be corrected within write latency is determined once again. Then, when a replacement block exists, the dirty block is replaced and logic physical address mapping information is then updated, or a replacement block is newly allocated to write data in the new replacement block and logic physical address mapping information is then updated. This will be described in more detail with reference to the accompanying flow chart.

According to the embodiment of the present invention, an arbitrary value is set for the number of ECC correction bits, and the corresponding replace flag is managed. Therefore, a block in which a read fail is highly likely to occur may be controlled to be reasonably used.

The memory controller 140 controls the memory area 150 to write, erase, and read data. The memory area 150 may include a NAND flash memory. In this embodiment of the present invention, memory cells of the NAND flash memory may include single level cells (SLC) or multi-level cells (MCL). The memory area 150 includes a plurality of chips, and each of the chips includes a plurality of blocks each having a plurality of pages.

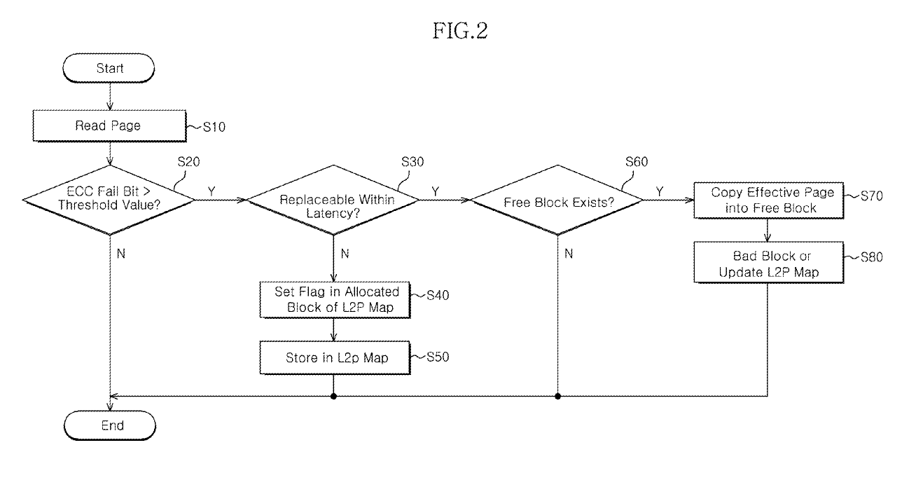

FIG. 2 is a flow chart showing a method for controlling a read operation based on FIG. 1.

Referring to FIG. 2, first, pages of a corresponding block are read at step S10.

After the pages are read, whether the corresponding block is a dirty block or not is determined at step S20.

At this time, whether the number of ECC correction bits of the corresponding block exceeds a predetermined threshold value or not is determined.

As described above, a bit error occurring during the read operation may be corrected through the error detection and correction technology. As the read operation is performed repetitively, the likelihood of occurrence of a read fail gradually increases. In data of which an error has been corrected, it is highly likely that an error additionally occurs during a next read operation. As such, when the bit correction number exceeds an allowable number, the corresponding block is processed as a dirty block.

Here, the predetermined threshold value is set to a smaller number than the maximum number of ECC correction bits. Then, when the number of ECC correction bits of the corresponding block is less than the predetermined threshold value, the read operation is ended by returning the read data.

However, when the number of ECC correction bits of the corresponding block exceeds the predetermined threshold value, the corresponding block is considered as a dirty block.

According to the embodiment of the present invention, when the number of ECC correction bits of the corresponding block is determined, the cause of the increase of the number of ECC correction bits needs to be determined. That is, whether the increase is caused by read disturbance or an erase-write (E/W) cycle needs to be determined.

As well known, electrons may be injected into a floating gate of an unselected memory cell transistor in a substrate during a read operation. That is, a phenomenon in which an unselected memory cell transistor having an on state (or erase state) is soft programmed under a bias condition of the read operation may be referred to as “read disturbance”. An increase of threshold voltage by the read disturbance may cause a read fail.

Therefore, by additionally determining the number of E/W cycles based on the determination of a dirty block, it is possible to determine whether the dirty block is worn out by repetitive program and erase operations or caused by the read disturbance. For example, when the number of ECC correction bits is equal to or larger than the threshold value and the E/W cycle number is also high, the corresponding block is a worn-out dirty block. Therefore, since the corresponding block is difficult to reuse, the block is processed as a bad block. However, when the number of ECC correction bits is equal to or larger than the threshold value and the E/W cycle number is low, the corresponding block is a dirty block caused by read disturbance. Therefore, the corresponding block is difficult to use as a free block for a bad block, but may be reused as a temporary block or predetermined buffer block having a small storage area.

In other words, according to the embodiment of the present invention, the threshold value of the ECC fail bits and the E/W cycle number may be used to replace a dirty block and determine whether the dirty block is reused or not.

Subsequently, whether a dirty block can be replaced with a replacement block within read latency or not is determined at step S30.

In the case of a flash memory apparatus, the time required for reading one page is equal to or less than several hundreds us, for example.

When it is determined that the corresponding block cannot be replaced with another block during the read operation, that is, the read latency, a replace flag is set in a logic physical address mapping table to command that the corresponding block should be replaced with another block during a subsequent write operation, at step S40. Then, the logic physical address mapping table is stored at step S50.

Meanwhile, when it is determined that a dirty block can be replaced with a replacement block within the read latency, whether a free block to be used as a replacement block exists or not is determined at step S60.

When it is determined that a dirty block can be replaced with a replacement block during the read latency but a free block to be used as a replacement block does not exist, only the read data is returned, and the read operation is ended.

Then, the memory block including the read data is replaced with an extra reserved memory block or free block which is provided in a flash memory apparatus, through a separate relief method known as a block replacement method.

As well known to those skilled in the art, in the flash memory apparatus, merge means that all effective data stored in an original block is copied into another block and the original block is erased, in order to make one or more programmable blocks, and defective block replacement means that data of a block in which a program error occurs while a write command is carried out is copied into another normal block.

However, when it is determined that a dirty block can be replaced with a replacement block during the read latency and a free block to be used as the replacement block exists, a valid page is copied into the free block, and the dirty block is replaced with the free block, at step S70. The information of the dirty block is erased, and the information of the block which has been newly selected and completely copied is stored, that is, the logic address mapping information is updated and stored at step S80.

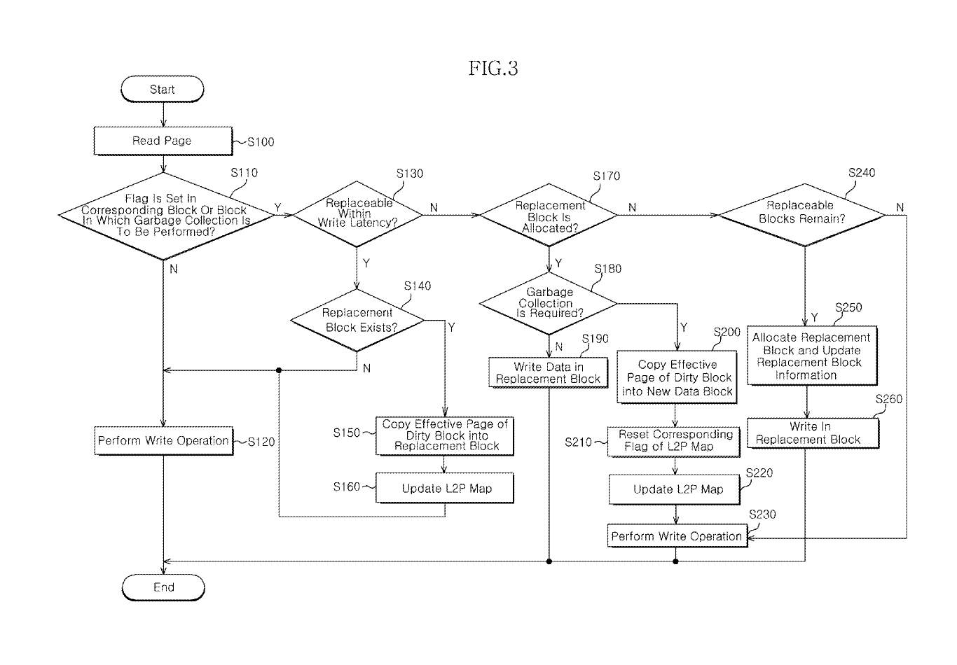

FIG. 3 is a flow chart showing a method for controlling a write operation based on FIG. 1.

Referring to FIG. 3, when it is determined that a write command is inputted at step S100, it is determined whether or not a replace flag is set in a corresponding block or a target block in which a garbage collection is to be performed, at step S110.

When it is determined that the replace flag is not set, the corresponding block does not need to be replaced, and a write operation is just performed at step S120.

When it is determined that the replace flag is set (Yes), whether the corresponding block can be replaced within the write latency or not should be determined at step S130.

When it is determined that the corresponding block can be replaced within the write latency (Yes), whether a replacement block exists or not is determined at step S140. When it is determined that the replacement block does not exist (No), a write operation is just performed at step S120. When it is determined that the replacement block exists (Yes), effective pages of the dirty block are copied into the replacement block at step S150. The information on the dirty block is erased, the block which was newly selected and into which the effective pages of the dirty block have been completely copied is allocated as a logic block, and the logic address mapping information is updated at step S160. Then, an access to the dirty block is substantially prevented.

If it is determined that a write busy time is lengthened due to a variety of operations for performing a data write operation and is to have an effect upon the write latency, that is, when it is determined that the corresponding block cannot be replaced within the write latency (No), whether a replacement block for the replacement operation within the write latency is allocated or not needs to be checked at step S170.

When it is determined that the replacement block is allocated (Yes), whether or not garbage collection is required for a block allocated as the replacement block is determined at step S180.

When it is determined that the garbage collection is not required, a write operation is just performed on the allocated replacement block at step S190. When it is determined that the garbage collection is required, the garbage collection operation is performed at step S200.

That is, the effective pages of the replacement block and the dirty block are copied into a new data block.

Accordingly, the replace flag set in the corresponding block of the logic physical address mapping table is reset to notice that the replacement operation has been already completed, at step S210.

The logic physical address mapping table into which even the reset result has been reflected is updated at step S220, and a write operation is subsequently performed in the replaced block at step S230.

Now, the case in which the replacement operation cannot be performed within the write latency and a replacement block is not allocated (steps S130 to 170) will be described.

Whether a replaceable block exists or not is determined at step S240. When it is determined that no extra replaceable block does not exist (No), it may be considered that all free blocks allocated for a dirty block or bad block have been used. Therefore, only a write operation is just performed at step S120, and the process is ended.

Fortunately, when it is determined that replaceable blocks exist (Yes), a replacement block is allocated, and information on the replacement block is updated at step S250.

Then, data is written into the replacement block at step S260, and the process is ended.

As such, before a number of bits which may be corrected by the ECC circuit is not exceeded, a block is replaced.

According to the embodiment of the present invention, when the number of ECC fail bits is equal to or larger than the threshold value, the corresponding block is replaced with another block, and effective information of the corresponding block is copied into the replaced block, thereby preventing the number of ECC correction bits from being exceeded.

In other words, whether the number of ECC fail bits is equal to or larger than the threshold value or not is determined for an error occurring during a read operation. Then, when it is determined that the number of ECC fail bits is equal to or larger than the threshold value, the corresponding block is controlled to be replaced even during a read or write operation.

When the time required for the corresponding operation (read operation) is more insufficient than that required for the replacement operation, a flag may be set to perform the replacement operation after the corresponding operation is completed. Then, the replacement operation is performed during a subsequent write operation.

Therefore, while guaranteeing quick response and real-time operations required by the flash memory system, it is possible to guarantee data within the likelihood of ECC correction. Furthermore, it is possible to prevent the occurrence of a serious system bottleneck.

While certain embodiments have been described above, it will be understood to those skilled in the art that the embodiments described are by way of example only. Accordingly, the method described herein should not be limited based on the described embodiments. Rather, the method described herein should only be limited in light of the claims that follow when taken in conjunction with the above description and accompanying drawings.

What is claimed is:

1. A method for controlling a nonvolatile memory apparatus in a nonvolatile memory system including a host interface, a memory controller, and a memory area, the method comprising:
checking a number of ECC fail bits, determining whether or not to replace a corresponding block, and replacing the block, while a read command provided from the host interface is performed; and
replacing a block, which was not replaced during the read operation, with a block to be used as a replacement target during a write operation.

2. The method according to claim 1, wherein the determination of whether or not to replace the corresponding block comprises setting a threshold number of ECC fail bits and determining whether the number of ECC fail bits of the corresponding block exceeds the threshold number or not.

3. The method according to claim 2, wherein the threshold number of ECC fail bits is set to be smaller than a maximum number of ECC correction bits.

4. The method according to claim 2, wherein when the number of ECC fail bits is larger than the threshold number, the replacement of the corresponding block is determined.

5. The method according to claim 4, wherein when the number of ECC fail bits and the threshold number are compared, the corresponding block is erased, and a number of write cyclesis additionally referred to.

6. The method according to claim 1, wherein while the read command is performed, the replacement of the corresponding block is varied on the basis of an operation state of the nonvolatile memory system.

7. The method according to claim 6, wherein when a time required for replacing the corresponding block is sufficient during the read operation, the corresponding block is replaced, and when the time is not sufficient, the corresponding block is replaced during the next write operation.

8. The method according to claim 1, wherein when a time required for replacing the corresponding block is sufficient during the write operation, the corresponding block is replaced, and when the replacement of the corresponding block and garbage collection are required, effective pages of the corresponding block are copied into a new block, and logic physical address information is updated and stored.

9. A method for controlling a nonvolatile memory apparatus in a nonvolatile memory system including a host interface, a memory controller, and a memory area, the method comprising:
checking a number of ECC fail bits, discriminating whether a corresponding block is a dirty block caused by read disturbance or a worn-out dirty block, and setting a replace flag for whether or not to replace the corresponding block, while a read command provided from the host interface is performed; and
replacing a block, in which the replace flag is set, with a block to be used as a replacement target during a write operation.

10. The method according to claim 9, wherein the determination of whether or not to replace the corresponding block comprises setting a threshold number of ECC fail bits, determining whether the number of ECC fail bits of the corresponding block exceeds the threshold number or not, and additionally referring to an erase and number of write cycles of the corresponding block.

11. The method according to claim 10, wherein the threshold number of ECC fail bits is set to be smaller than a maximum number of ECC correction bits.

12. The method according to claim 10, wherein when the number of ECC fail bits is larger than the threshold number, the replacement of the corresponding block is determined.

13. The method according to claim 10, wherein when the number of ECC fail bits is larger than the threshold number and the number of erase and write cycles of the corresponding block is higher than a predetermined value, the corresponding block is determined to be a worn-out block, replaced with a new block, and then processed as a bad block.

14. The method according to claim 10, wherein when the number of ECC fail bits is larger than the threshold number and the number of erase and write cycles is lower than a predetermined value, the corresponding block is determined to be a dirty block caused by read disturbance, replaced with a new block, and then reused as a temporary block.

15. The method according to claim 11, wherein the block in which the replace flag is set is replaced during a write operation.

16. A method for controlling a nonvolatile memory apparatus in a nonvolatile memory system including a host interface, a memory controller, and a memory area, the method comprising:
checking a number of ECC fail bits to determine whether a corresponding block is a dirty block or not, setting the dirty block to a block to be replaced, and discriminating whether or not to reuse the dirty block, while a read command provided from the host interface is performed; and
replacing the dirty block, which was not replaced while the read command was performed, with a block to be used as a replacement target during a write operation.

17. The method according to claim 16, wherein the determination of whether or not to replace the dirty block comprises setting a threshold number of the ECC fail bits, determining whether the number of ECC fail bits of the dirty block exceeds the threshold number or not, and additionally referring to a number of erase and write cycles of the dirty block.

18. The method according to claim 17, wherein the threshold number of ECC fail bits is set to be smaller than a maximum number of ECC correction bits.

19. The method according to claim 17, wherein when the number of ECC fail bits is larger than the threshold number, the replacement of the dirty block is determined.

20. The method according to claim 17, wherein when the number of ECC fail bits is larger than the threshold number and the number of erase and write cycles of the corresponding block is larger than a predetermined value, the dirty block is replaced with a new block, and then processed as a bad block.

21. The method according to claim 17, wherein when the number of ECC fail bits is larger than the threshold number and the number of erase and write cycles of the corresponding block is lower than a predetermined value, the dirty block is replaced with a new block, and then reused as a temporary block.

22. The method according to claim 16, wherein when a time required for replacing the dirty block is sufficient during the write operation, the dirty block is replaced, and when the replacement of the dirty block and garbage collection are required, effective pages of the dirty block are copied into a new block, and logic physical address information is updated and stored.
